(19) United States
(12) Patent Application Publication
(10) Pub. No.: US 2019/0237228 A1
(43) Pub. Date: Aug. 1, 2019

(54) PRINTED FLEXIBLE ELECTRONIC DEVICES CONTAINING SELF-REPAIRING STRUCTURES

(71) Applicant: The Regents of the University of California, Oakland, CA (US)

(72) Inventors: Joseph Wang, San Diego, CA (US); Amay Jairaj Bandodkar, La Jolla, CA (US)

(21) Appl. No.: 16/341,016

(22) PCT Filed: Oct. 12, 2017
(86) PCT No.: PCT/US17/56414

§ 371 Date: Apr. 10, 2019

Related U.S. Application Data
(60) Provisional application No. 62/407,439, filed on Oct. 12, 2016.

(51) Int. Cl. H01F 1/057; H05K 1/18; H01F 41/16

(52) U.S. Cl. CPC H01F 1/0572; H05K 1/181; C22C 38/005; H05K 2201/10037; H05K 2201/10151; H01F 41/16

(57) ABSTRACT

Articles, devices and machines are disclosed for initiating structural changes based on material magnetic properties to cause self-adjustment to improve the operation or function of structures, devices or machines. In one aspect, a device exhibiting a self-healing property to repair a damage, the device including a device structure over which magnetic microparticles are dispersed to impart a self-healing ability to enable the device structure, once damaged to have a broken portion, to self-repair based on magnetic attraction of the dispersed magnetic microparticles to cause re-attachment of the broken portion.

### CROSS-REFERENCE TO RELATED APPLICATIONS

This patent document claims the priority to and benefits of U.S. Provisional Patent Application No. 62/407,439 entitled “ALL-PRINTED MAGNETICALLY SELF-HEALING ELECTROCHEMICAL DEVICES” filed on Oct. 12, 2017. The entire content of the aforementioned patent application is incorporated by reference as part of the disclosure of this patent document.

### STATEMENT REGARDING FEDERALLY SPONSORED RESEARCH OR DEVELOPMENT

This invention was made with government support under Grant R21EB019698 awarded by the National Institutes of Health (NIH) and Grant DE-AR0000535 awarded by Advanced Research Projects Agency-Energy (ARPA-E). The government has certain rights in the invention.

### TECHNICAL FIELD

This patent document relates to materials, structures, devices, and processes based on magnetic material properties.

### BACKGROUND

Various artificial devices, structures and machines, once made, tend to exhibit various undesired states, structural or functional, due to various factors including device or material aging and degradation, tears and wears, changes caused by the use or operation, or changes caused by the surrounding environments, or others. Often, repairs, reconditioning or adjustments may be needed to restore, at least at some level, the device, structure, or machine to a better state.

### SUMMARY

This patent document discloses, among others, structures, devices or machines that can initiate structural changes based on material magnetic properties to cause self-adjustment to improve the operation or function of structures, devices or machines.

In some aspects, a device exhibiting a self-healing property to repair a damage includes a device structure including a plurality of magnetic microparticles dispersed within the device structure and oriented with respect to each other such that their magnetic poles are substantially aligned, in which the plurality of magnetic microparticles are configured to impart a self-healing ability to the device structure such that, when damage occurs to a portion of the device structure, the device structure is able to self-repair based on magnetic attraction of the dispersed magnetic microparticles to cause re-attachment of the portion.

In some aspects, a method for producing a self-healing electronic circuit component includes depositing an adhesion layer at a region of a substrate to adhere an electrically conductive material that will form an electronic circuit component; printing a self-healing printable ink over the deposited adhesion layer to form the electronic circuit component, in which the self-healing ink includes a containment material, a plurality of permanent magnetic particles dispersed in the containment material and oriented with respect to each other such that their magnetic poles are substantially aligned, and a filler material that is electrically conductive, in which the plurality of permanent magnetic particles are configured to autonomously repair a damaged portion of the printable ink based on magnetic attraction of the permanent magnetic particles in the containment material; applying a magnetic field one or both of during and after the printing the self-healing printable ink; and forming the electronic circuit component by curing or drying the self-healing printed ink.

In some aspects, a self-healing article includes a containment material; and a plurality of permanent magnetic particles dispersed in the containment material and oriented with respect to each other such that their magnetic poles are substantially aligned, in which the plurality of permanent magnetic particles are configured to autonomously repair a damage to the article based on magnetic attraction of the permanent magnetic particles in the containment material.

In some aspects, a printable ink includes an ink binder material; a plurality of permanent magnetic particles dispersed in the ink binder material and oriented with respect to each other such that their magnetic poles are substantially aligned; and a filler material contained in the ink binder, in which the filler material is electrically conductive, in which the printable ink is structured to autonomously self-repair a damaged portion based on orientation of the permanent magnetic particles in the ink binder to produce an anisotropic magnetic field within the printable ink.

Specific examples disclosed herein demonstrate the synthesis and application of example embodiments of a self-healing article including permanent magnetic Nd₂Fe₁₄B microparticles (NMPs) loaded graphitic inks for realizing rapidly self-healing inexpensive printed electrochemical devices. For example, the incorporation of NMPs into the printable ink imparts impressive self-healing ability to the printed conducting trace, with rapid (e.g., ˜50 ms) recovery of repeated large (e.g., 3 mm) damages at the same or different locations without any user intervention or external trigger. The permanent and surrounding-insensitive magnetic properties of the example NMPs thus result in long-lasting ability to repair extreme levels of damage, independent of ambient conditions. For example, such remarkable self-healing capability has not been reported for existing man-made self-healing systems, and offers distinct advantages over common capsule and intrinsically self-healing systems. Example implementations of the example printed system characterized the system by leveraging crystallographic, magnetic hysteresis, microscopic imaging, electrical conductivity and electrochemical techniques. The real-life applicability of the new self-healing technology is demonstrated towards the autonomous repair of all-printed batteries, electrochemical sensors, and wearable textile-based electrical circuits, among other applications, which may be used for widespread potential practical applications and long-lasting printed electronic devices.

### BRIEF DESCRIPTION OF THE DRAWINGS

FIG. 1A shows an illustrative diagram of an example embodiment of a permanent magnetic self-healing material article in accordance with the present technology.

FIG. 1B shows illustrative diagrams and accompanying images of an example implementation of a self-healing material article used in an electrical circuit, broken and self-repaired, which demonstrates the autonomous recovery of the self-healing material article upon complete damage.

FIG. 1C shows a pictorial representation of an example printing process for realizing the self-healing trace.

FIG. 2A shows a spectra data plot of X-Ray Diffraction (XRD) measurements for an example NMPs.

FIG. 2B shows a data plot depicting magnetic hysteresis curves for example NMPs and example self-healing trace.

FIG. 2C shows a multi-panel data plot featuring Scanning Electron Microscopy (SEM) and Energy Dispersive X-Ray Analysis (EDX) data for example printed traces including neodymium and carbon samples.

FIG. 3A-3D show electrical conductivity vs time plots and corresponding illustrations depicting the self-healing ability of an example self-healing printed trace.

FIG. 4 shows data plots for a cyclic voltammetric analysis of example printed self-healing traces at various conditions.

FIGS. 5A-5D show data plots and photographs depicting the self-healing ability of an example self-healing Zn—Ag₂O battery.

FIGS. 5E and 5F show data plots depicting the self-healing ability of example self-healing electrochemical sensors.

FIG. 7 shows an illustrative diagram of another example for using an example self-healing device in accordance with the disclosed technology, such as a battery.

FIG. 8 shows an illustrative diagram of another example for using an example self-healing device in accordance with the disclosed technology, such as a sensor.

FIG. 9 shows an illustrative diagram of an example self-healing circuit device containing a layer of an example printed magnetically self-healing material to impart a self-healing property to the circuit.

### DETAILED DESCRIPTION

Degradation of structures and devices caused due to mechanical deformation and the concomitant dysfunctioning of man-made systems is a major cause of concern in numerous technological fields. Extensive efforts have been devoted for addressing this issue by developing new stretchable and tough materials that can withstand mechanical deformations and thus augment the lifespan of the structures and devices. However, stretchable devices fail if the strain exceeds a particular limit.

Biological systems have addressed this issue by mastering remarkable self-healing properties. Taking cue from nature, materials scientists have recently focused on developing innovative materials for realizing man-made self-healing systems. The enhanced life-time of such self-healing systems is quite attractive, especially in scenarios where replacing a mechanically damaged component is either expensive and/or cumbersome. Fragility is the “Achilles Heels” of the multi-billion dollar field of printed electronics. Development of self-healing inks will thus be germane to printed electronics towards their numerous applications in scenarios where mechanical damage of devices is common.

Man-made self-healing systems have been commonly based on micro-capsules, vesicles or intrinsic properties. Of these, micro-capsule-based systems have been explored for realizing self-healing printed devices. Although attractive, capsule-based systems have several inherent limitations. For example, such systems cannot self-heal multiple damages at the same location since almost all the capsules along the path of the damage get ruptured, and in-situ refilling of the broken capsules is impossible. These cannot heal macroscopic cracks. Furthermore, the capsules are usually much larger than the conductive particles of the inks, and thus compromise their uniform dispersion within the printed film. Therefore, healing takes place only at locations where capsules are present. Increasing the capsule loading is an unviable route to achieving homogeneous dispersion since the non-conductive nature of the capsules significantly increases the resistivity of the printed films. Additionally, the capsules encapsulate an organic solvent which can gradually evaporate through the minute pore defects in the capsule wall, thus limiting the lifespan of the healing ability. Moreover, an organic-solvent based healing system is unsuitable for various applications, such as wearable/implantable electronics, where the device is in intimate contact with biological tissues.

The disclosed technology in this patent document can be used to address the above challenges by developing magnetically self-healing materials. In some embodiments, a magnetically self-repairing graphitic ink has been formulated to include permanent magnetic Nd₂Fe₁₄B microparticles (NMPs) that impart remarkable self-healing ability to the printed films. We refer to the self-healing process as intrinsic-based since the NMPs are uniformly dispersed within the ink, thus allowing the printed system to self-repair irrespective of the location of damage—a property characteristic of intrinsically self-healing systems. Example implementations of the example NMP graphitic ink showed strong magnetic attraction between the NMPs that allows the printed films to spontaneously and autonomously recover the mechanical and electrical contacts of devices using the ink, e.g., even when the damage was as wide as 3 mm (e.g., notably, a feat that has not been reported to date by any self-healing system).

Conventional self-healing systems, including existing systems using intrinsic properties, are incompatible with printing processes, limited to microscale damages, require external trigger to initiate the healing process, manual pressing of the broken pieces, very long self-healing time, and/or must be hydrated and the broken pieces must be joined immediately. Furthermore, existing intrinsically self-healing systems rely on special chemistries for initiating the self-recovery process. Such chemistry-based self-healing processes can be easily inhibited by the ambient conditions.

The disclosed magnetic self-healing materials, structures, devices, and processes in accordance with the present technology addresses and overcomes the above problems and limitations faced by conventional systems, such as capsule and intrinsic based self-healing systems, e.g., since the magnetic nature of the healing process permits the printed devices to instantly self-restore multiple damages at the same or different locations without the requirement of external trigger. In addition, for example, the conductive nature of the NMPs of the example inks does not affect the resistivity of the printed trace and the permanent magnetism of the NMPs imparts remarkably long-lasting self-healing capability for numerous repair events. Compared to many intrinsically self-healing systems, for example, the disclosed self-healing process relies on the physical attraction between NMPs which is unaffected by a wide range of ambient conditions.

Other examples of conventional magnetically self-healing systems rely on iron-oxide particles and thus require an external trigger to initiate the self-healing process. In contrast, the disclosed self-healing material system is based on NMPs that have permanent magnetic properties and hence it autonomously initiates the healing process. Furthermore, in some implementations of processes in accordance with the present technology, computer simulations and models are employed to predict a system's behavior based on the attractive forces between magnetic particles, which can be exploited to design novel inks with tailor-made self-healing properties. Example implementations of the disclosed magnetic self-healing materials, devices, systems and processes are described which demonstrates example synthesis techniques of the magnetically self-healing graphite ink towards realizing all-printed self-healing electrochemical sensors, batteries and wearable textile-based electrical circuits that can instantly recover repeated macroscopic damages, e.g., as wide as 3 mm at the same or different locations. The example self-healing ink formulation technique discussed herein can be easily applied for developing inks containing other fillers for printing self-healing devices that cater to a wide range of applications and printed electronic devices.

### Example Embodiments

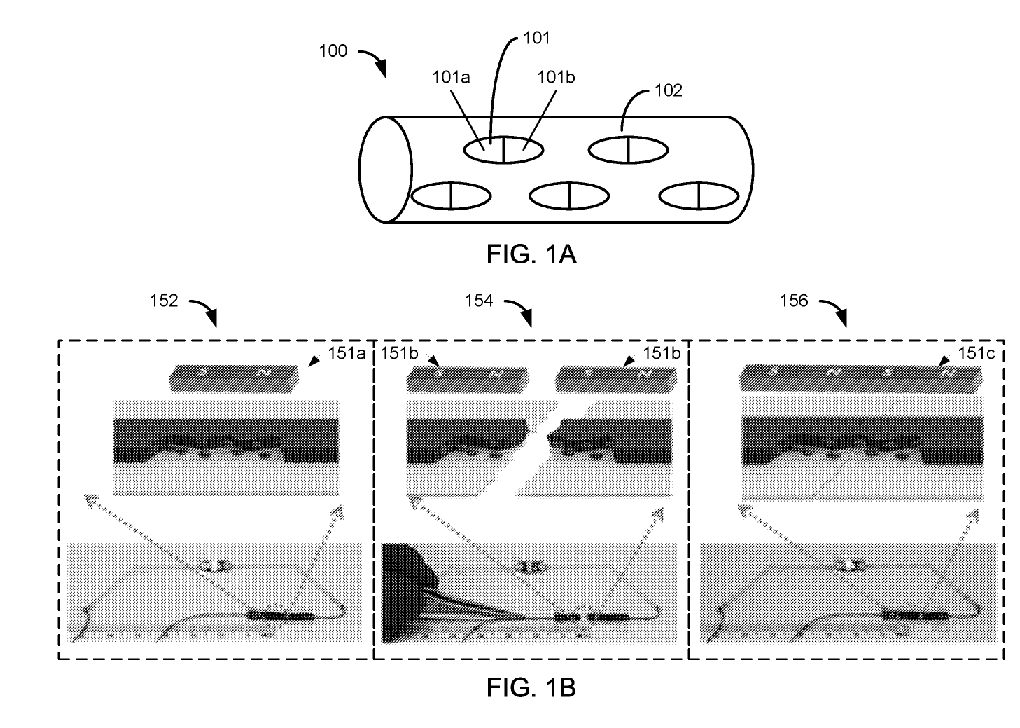

FIG. 1A shows an illustrative diagram of an example embodiment of a permanent magnetic self-healing material article 100, e.g., in the form of a printable ink, which can be used to make self-healing devices and systems. The self-healing material article 100 includes a containment material 102 that encapsulates and suspends permanent magnetic particles 101 within the containment material 102. In some implementations, the self-healing material article 100 is produced such that the permanent magnetic particles 101 are dispersed in the containment material 102 and oriented with respect to one another such that their magnetic poles are substantially aligned. The configuration of the permanent magnetic particles 101 provides the article 100 with the capability to autonomously self-repair when damage occurs to the article, in which the article self-repairs based on magnetic attraction of the permanent magnetic particles 101 in the containment material 102, e.g., which can reconnect disconnected region of the article 100 due to the damage. In some embodiments, the permanent magnetic particles 101 are able to shift or change their orientations within the containment material 102, which allows them to orient themselves according to their own magnetic properties, and/or to react to external stimuli such as an applied magnetic field, to affect the structure of the self-healing material 100.

The permanent magnetic particles 101 include micrometer- or nanometer-sized particles having a magnetic material, such as a ferromagnetic or ferrimagnetic material, to provide magnetic properties of a permanent magnet for the particles. The magnetic material of the particle 101 includes a first magnetic pole 101a (e.g., N or S) and a second magnetic pole 101b (e.g., S or N) opposite that of the first magnetic pole 101a. In some embodiments, the permanent magnetic particles 101 are microparticles structured to have a size in a range of 1 μm to 10 μm. Whereas, in some embodiments, the permanent magnetic particles 101 are nanoparticles structured to have a size in a range of 100 nm to 1,000 nm. In some embodiments, the permanent magnetic particles 101 are formed of magnetic materials with high coercivity, e.g., about 70 Oe or more. Such examples can include, but are not limited to, neodymium-iron-boron (Nd₂Fe₁₄B), alnico alloys (AlNiCo), samarium cobalt (SmCo₅), BaO-6Fe₂O₃, cunife, tungsten steel, or others. For example, the permanent magnetic particles 101 can include any magnetic material for the magnetic self-healing material article 100 based on the material of the containment material 102 or application of the article 100.

In some examples, the containment material 102 comprises a liquid or gel medium including one or more of a solvent or solvents, a pigment or pigments, a dye or dyes, a resin or resins, a lubricant or lubricants, a solubilizer or solubilizers, a surfactant or surfactants, a particulate or particulates, and/or a fluorophore or fluorescent substance or substances, or other materials. Such example constituents can be included in the containment material to provide color, texture, and/or viscosity, in addition to a structure to contain and carry and/or flow the permanent magnetic particles 101 within the containment material 102. In some example embodiments, the containment material 102 (e.g., ink) includes one or more of an enzyme or enzymes, an antibody or antibodies, electrochemical redox species, and/or nano/microparticles of metals, metal oxides, metal chalcogenides, ceramics, quantum dots or other material for making various types of printable inks for realizing bioelectronics devices, optical systems, batteries, or energy harvesting systems, or other applications.

In some example embodiments, the containment material 102 can also contain elastomeric polymers for realizing soft, stretchable printed devices for various wearable, bio-integrated applications or other applications. For example, the self-healing article 100 can include an elastomeric polymer contained in the containment material 102, e.g., which, in combination with the permanent magnetic particles 101, can assist in the self-healing of the article 100 when damaged. In example embodiments of the article 100 including a printable ink that contains the permanent magnetic particles and one or more elastomeric polymers, the magnetic particles can lead to instantaneous connection of damaged portions (e.g., cracked or broken pieces) of the article 100, such that when the broken the pieces are magnetically connected, the self-healing polymers on either side of the cracks will undergo chemical interaction to form permanent bonds, e.g., thereby permanently sealing the crack.

FIG. 1B shows illustrative diagrams and accompanying images of an example implementation of the self-healing material article 100 used in an electrical circuit, broken and self-repaired, which demonstrates the autonomous recovery of the self-healing material article 100 upon complete damage. In the example implementation, the damage width of the article 100 was 3 mm. As shown in the top portion of FIG. 1B, the illustrative diagrams depict the working principle of the self-healing process. In this example, a printed self-healing trace that comprises Nd₂Fe₁₄B microparticles (NMPs) is coupled to a circuit including a light, as shown in the left caption 152. The NMPs of the self-healing material align within the article, which produce a net magnetic field along the length of the trace, e.g., analogous to a bar magnet (like that depicted by magnet 151a used for comparative illustration). The printed self-healing trace then damaged, e.g., with a 3 mm separation between two sides of the trace, as shown in the center caption 154. Due to the alignment of NMPs in the self-healing material and the produced net magnetic field along the trace, the trace is able to repair itself. When the trace is severed, for example, the two pieces behave analogous to individual bar magnets with opposite poles attracting each other (like that depicted by magnets 151b used for comparative illustration). The strong magnetic attraction between the two severed pieces forces them to move towards each other to regain the mechanical and electrical connectivity, e.g., exemplified by the light in the circuit, as shown in the right caption 156.

FIG. 1C shows a pictorial representation of an example printing process for realizing the self-healing trace, like that shown in FIG. 1B. The illustration of FIG. 1C shows the initial random orientation of the NMPs within the printed trace (left) and the gradual alignment (right).

Example Implementations and Results

Ink Formulation, Printing Process and Self-Healing Property

In some implementations of the disclosed technology, the self-healing article 100 includes a printable ink that can address issues inherent to capsule and intrinsic based self-healing systems for realizing rapidly self-healing low-cost printed electronic devices, e.g., with special emphasis on electrochemical sensors and batteries. NMPs have several advantages for realizing conductive self-healing systems. For example, NMPs have a strong permanent magnetic field that can span an area much larger than their size. They have high electrical conductivity and therefore can be used for realizing conductive devices. Furthermore, Nd₂Fe₁₄B is inexpensive and widely available. Therefore, Nd₂Fe₁₄B was considered as a material for the permanent magnetic particles in applications of an article as ink filler to impart self-healing ability. Although NMPs have high conductivities, they do have poor electrochemical properties as was noticed during preliminary cyclic voltammetric experiments. Carbon black (CB) is a widely explored material for fabricating electrochemical systems, such as batteries and sensors owing to its high conductivity, large surface area and low-cost. Therefore, CB was considered as the second filler component of the self-healing ink to incorporate favorable electrochemical properties to the printable self-healing ink. Polystyrene-block-polyisoprene-block-polystyrene (SIS) was considered as the ink binder as it offers homogeneous dispersion of both NMPs and CB and firmly binds the fillers to avoid material loss when exposed to liquid media, as demonstrated later in various electrochemical experiments (described below).

The healing ability of the example system relies on the orientation of the net magnetic field of the permanent magnetic particles 101 (e.g., NMPs) dispersed within the containment material 102 (e.g., ink) to form a self-healing printed film. For example, in the absence of an external magnetic field, the magnetic field of an individual NMP would be neutralized by that of neighboring NMPs, e.g., leading to an article such as a printed film with a net zero magnetic field. Such films would fail to demonstrate self-healing property due to the absence of an anisotropic magnetic field within the printed film. The autonomous self-healing articles, devices and systems in accordance with the present technology include a structure that orient the permanent magnetic particles 101 in the containment material 102 to align their magnetic poles such that the permanent magnetic particles 101 produce an anisotropic magnetic field within the article, device or system.

This issue was evaluated in example implementations that include producing a printable ink in the presence of an external magnetic field (e.g., discussed in the Example Materials and Methods section). When the ink is printed onto the substrate, the NMPs are initially oriented randomly within the printable ink, which forms a printed trace on the substrate. However, the NMPs immediately orient themselves along the external magnetic field to produce a net magnetic field along the direction of the trace. The resulting printed film behaves like a permanent magnet with the two poles at the two ends of the trace, as depicted in caption 152 of FIG. 1B. When the printed trace is damaged, the two damaged pieces behave as individual permanent magnets, as depicted in caption 154 of FIG. 1B, which immediately attach to each other via magnetic force and thus self-heal, as depicted in caption 156 of FIG. 1B. For example, an attractive feature of the permanent magnetic nature of the example system is that the printed films demonstrate self-healing ability for large number of damage-heal cycles under a wide range of ambient conditions. For example, the strength of the magnetic force depends on the amount of magnetic particles (e.g., NMPs) in the containment material (e.g., ink) and the printed film is expected to have sufficient maximum energy product (BH)ₘₐₓ in order to impart rapid self-healing of macroscopic damages. (BH)ₘₐₓ is directly proportional to the volume fraction of the non-magnetic component as described by Eq. 1.

$${( BH )}_{max} ∝ {[ ( 1 - {V}_{non} ) \frac{d}{{d}_{m}} {B}_{r} ( p ) ]}^{2} \qquad ( 1 )$$

Here, ‘Vₙₒₙ,’ is volume fraction of the non-magnetic components; ‘d’ is the density of the magnet; ‘dₘ’ is the theoretical density of ideal bonded permanent magnetic particles (e.g., NMPs) and ‘Bᵣ(p)’ is the remanence magnetization of the permanent magnetic particles (e.g., NMPs). As evident from Eq. 1, higher the volume fraction of the example NMPs will lead to printed films with higher healing ability.

Therefore, example embodiments can include inks containing different ratios of different magnetic materials, such as NMPs and CB, and/or other constituents. An example ink containing different ratios of NMPs and CB were first prepared to identify the best composition that offered strong healing ability as well as attractive electrochemical response. Ultimately, for example, a weight ratio of 8:1 (NMPs:CB) was selected since it offered very rapid self-healing and a favorable electrochemical behavior. The self-healed films can be easily lifted against gravity without damaging the film at the healed location due to the strong magnetic attraction between the NMPs.

Microscopic Imaging and Magnetic Properties Analysis

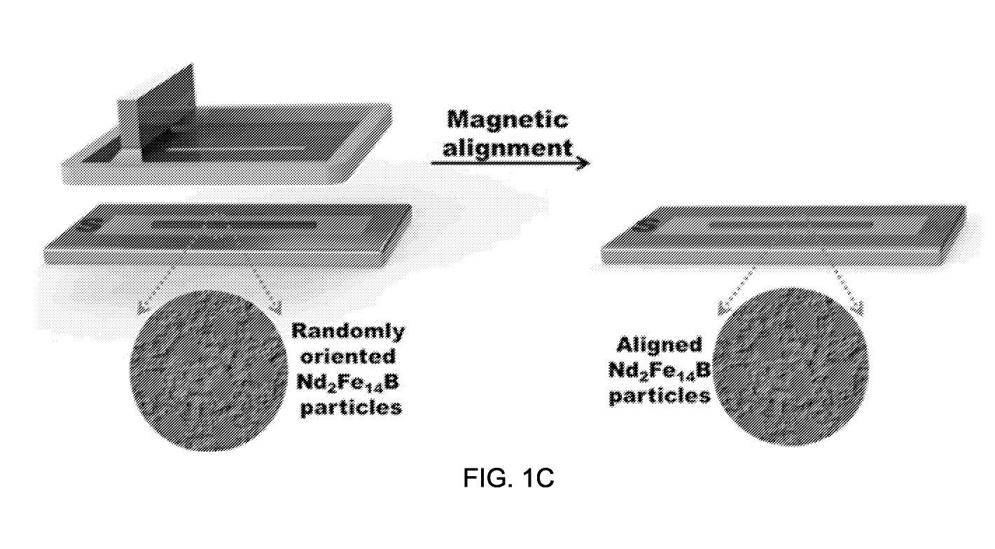

FIG. 2A shows a XRD spectra data plot for an example NMPs. FIG. 2B shows a data plot depicting magnetic hysteresis curves for example NMPs (black plot, 221) and self-healing trace (red plot, 222). FIG. 2C shows a multi-panel data plot featuring SEM and EDX data for printed traces including example neodymium and carbon samples. The multi-panel data plot of FIG. 2C shows an SEM image for an example self-healing trace article with aligned magnetic microparticles in panel (C), EDX data for neodymium of the aligned self-healing printed trace in panel (C′), and EDX data for carbon of the aligned self-healing printed trace in panel (C″). The multi-panel data plot of FIG. 2C shows an SEM image for an example self-healing trace article with unaligned magnetic microparticles in panel (D), EDX data for neodymium of the unaligned self-healing printed trace in panel (D′), and EDX data for carbon of the unaligned self-healing printed trace in panel (D″). The multi-panel data plot of FIG. 2C shows an SEM image of a printed trace based on a CB ink (no NMPs) in panel (E), 3D optical images of aligned printed traces in panel (F), and 3D optical images of unaligned printed traces (scale in μm). Example scale bars are 200 μm for panels (C), (C′), (C″), (D), (D′), (D″) and (E).

Example inks were prepared by first pulverizing Nd₂Fe₁₄B magnets in a high energy planetary ball milling machine. Such a process imposes intense mechanical stress on the magnets which can cause decrease in crystallinity and lead to decreased magnetic properties. XRD studies were performed on the example NMPs to analyze their crystallinity, shown in FIG. 2A. The positions of the numerous peaks observed for the sample were well correlated with standard peaks for Nd₂Fe₁₄B, e.g., indicating that pulverizing process has negligible impact on the crystallinity of Nd₂Fe₁₄B. Observing the magnetic hysteresis curve material provides a glimpse into a material's magnetic properties. For example, magnetic hysteresis curve was first recorded for bare NMPs at ambient temperature, as shown by plot 221 in FIG. 2B. The symmetrical hysteresis curve indicates that the intense milling process has minimal effect upon the alloy's ferromagnetic properties. Magnetic hysteresis curve was also analyzed for a printed self-healing trace (containing NMPs, CB and SIS) under similar ambient conditions. Plot 222 in FIG. 2B illustrates that the incorporation of the NMPs in the ink doesn't affect their ferromagnetic nature, indicating that the printed trace behaves as a ferromagnetic composite. It can be easily noted that the remanence for both NMPs and the printed trace is similar, while the coercivity for the printed trace is larger than that of the bare NMPs. For example, this can be attributed to the increased resistive nature of the non-magnetic components (CB and SIS) of the printed trace.

The magnetic alignment of the NMPs within the printed trace to produce a net anisotropic magnetic field is a crucial requirement for the self-healing process to occur. SEM-EDX technique was used to examine the effect of external magnetic field in aligning the NMPs within the printed trace. The alignment of the ink components along the direction of the external magnetic field is visible in the SEM image pf aligned traces, e.g., shown in panel (C) of FIG. 2C. The alignment is even more clearly noticeable in the EDX image obtained for neodymium, e.g., shown in panel (C′) of FIG. 2C. The strong magnetic arrangement of the NMPs also orient the CB particles, as evident from the EDX image captured for carbon, e.g., shown in panel (C″) of FIG. 2C. Additionally, the EDX study sheds insights into the degree of homogeneity for CB and NMPs within the printed trace. During the printing process, for example, the ink is still wet and thus the NMPs can possibly separate out due to the external magnetic field and can lead to a printed trace with heterogeneous distribution of NMPs and CB. Such non-uniformly distributed trace can be undesirable, e.g., since it leads to self-healing ability only at locations where NMPs are available and also results in poor electrochemical response. The respective EDX data for carbon and neodymium in the aligned printed trace clearly demonstrates that the NMPs do not separate out and that CB and NMPs maintain their uniform dispersion. This could be attributed to the viscous nature of the ink that prohibits physical displacement of the NMPs but permits their rotation to align their respective magnetic fields along that of the external field.

In contrast, the SEM-EDX analysis of the non-aligned printed trace (fabricated in absence of an external magnetic field), reveal a completely different morphology with no alignment of the NMPs, e.g., shown in panels (D), (D′) and (D″) of FIG. 2C. For example, although the NMPs and CB are uniformly distributed within the trace (panels (D′) and (D″)), the absence of the NMP alignment is the underlying reason for the printed trace's inability to demonstrate self-healing property. Panel (E) of FIG. 2C depicts the SEM image for a CB ink-based trace (no NMPs) as a control experiment. The image reveals that the trace has a much smoother morphology as compared to those captured for the aligned and non-aligned printed traces. This indicates that the higher surface roughness of the aligned and non-aligned traces is mainly due to the NMPs. Thereafter, 3D optical imaging was employed to study the surface of the aligned and non-aligned printed traces at a much larger scale, e.g., shown in panels (F) and (G) of FIG. 2C. There, it can be noted that the surface of the aligned printed trace is much smoother than that of its non-aligned counterpart. For example, this can be attributed to the presence of a strong magnet beneath the substrate during the printing of the aligned trace that causes the NMPs to not only align along the direction of the magnetic field but also get strongly attracted towards the underlying magnet. This strong downward attraction forces the printed ink into a well packed printed trace with low surface roughness. In contrast, for example, the absence of the underlying magnet while fabricating the non-aligned printed trace results in higher surface roughness.

Electrical Conductivity Studies for Evaluating Self-Healing Property

The example implementations included recording and analyzing the time required to recover a trace's conductivity upon complete damage to characterize the self-healing ability of the example embodiment of a self-healing material system. Preliminary experiments focused on studying the evolution of resistance of the printed self-healing trace under different conditions of damage. For example, an example advantage of the present system over the capsule and intrinsic property based systems is its ability to autonomously repair multiple macroscopic damages at the same location. The repeated repair ability of the new system was tested by coupling an example embodiment of a self-healing printed trace to a digital multi-meter, interfaced with a computer, to record its real-time resistance while the trace and the underlying substrate were completely severed multiple times at the same location into two pieces separated by cracks with increasing widths.

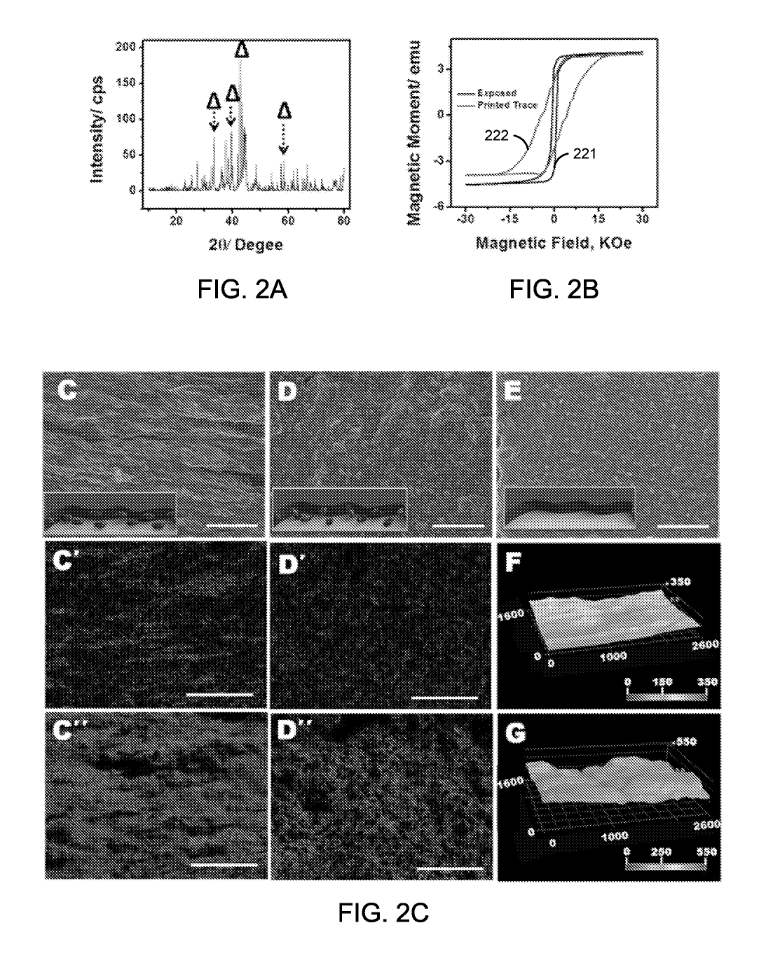

FIG. 3A-3D show electrical conductivity vs time plots and corresponding illustrations depicting the self-healing ability of an example self-healing printed trace. FIG. 3A shows the electrical conductivity of the example self-healing printed trace when repeatedly damaged at the same location with damage width ranging from 1 mm to 3 mm. FIG. 3B shows the electrical conductivity of the example self-healing printed trace when damaged at multiple locations (e.g., damage width=1 mm). Insets for the respective panels of FIGS. 3A and 3B show a zoomed-in portion of the plots illustrating the conductivity recovery of the self-healing traces upon damage. The dotted line of the inset plots represents the time when the self-healing process is allowed to take place.

As shown in FIG. 3A, the damage width was increased from 1 mm to 3 mm (step=1 mm). For example, for each damage width, the damage-heal cycle was repeated three times. It is evident from FIG. 3A, for example, that the trace can self-heal repeated damage at the same location even when the crack width is as wide as 3 mm with almost complete recovery of its electrical conductivity. It is important to point out that the actual healing time for the example system is significantly shorter than that apparent in the example of FIG. 3A. A major portion of the period where no conductivity is recorded was required to generate the damage of precise width; only a fraction of that time is actually required for the system to self-heal, as observed. The time required to complete the self-healing process was approximately 50 ms (e.g., represented by the dotted red line in the inset plot of FIG. 3A) and was calculated by the time required for the LED to turn ON after being damaged.

Practical real-life scenarios of the self-healing printed device may involve simultaneous multiple macroscopic damages at various locations. The ability of the example system to self-heal under such extreme situation was also examined by damaging a printed trace at multiple locations, e.g., with width=1 mm, shown in FIG. 3B. During this example study, the trace was first damaged at a location and was allowed to self-heal, e.g., shown in the left-most plot of FIG. 3B. Thereafter, the same trace was subjected to additional damage-heal cycles at locations adjacent to the first damage, e.g., shown in the two center plots and right-most plot of FIG. 3B. FIG. 3B demonstrates the ability of the printed trace to self-heal such multiple macroscopic damages with almost complete recovery of its conductivity (e.g., inset plot of FIG. 3B).

In addition to these example experiments, control studies analyzing the self-healing ability of a printed trace containing non-aligned NMPs and a trace printed using CB ink were also performed. FIG. 3C shows example results of the electrical conductivity studies revealing the inability of a printed traces including non-aligned NMPs to recover electrical connectivity when completely damaged. FIG. 3D shows example results of the electrical conductivity studies revealing the inability of a printed traces including only CB (e.g., no NMPs) to recover electrical connectivity when completely damaged. For example, the absence of an anisotropic magnetic field along the length of the trace renders the non-aligned printed trace without any self-healing ability, e.g., as shown in FIG. 3C. Similarly, for example, no self-healing ability is observed in the absence of NMPs in the CB ink-based trace, e.g., as shown in FIG. 3D. These example control experiments corroborate the importance of not only incorporating the NMPs, but also the need to align them during the printing process to impart autonomous self-healing ability.

Electrochemical Studies to Evaluate Self-Healing Properties

One of the aims of the example implementations includes demonstration of example embodiments of self-healing ink for realizing printed electrochemical devices. Cyclic voltammetric (CV) analysis was employed in the example implementations since it can offer an in-depth knowledge about the electrode-electrolyte interface along with useful insights into the effect of an electrode's composition on its electrochemical properties. Additionally, CV allows real-time probing of the electrochemical properties and thus can be used to study time-dependent processes occurring within the electrochemical cell.

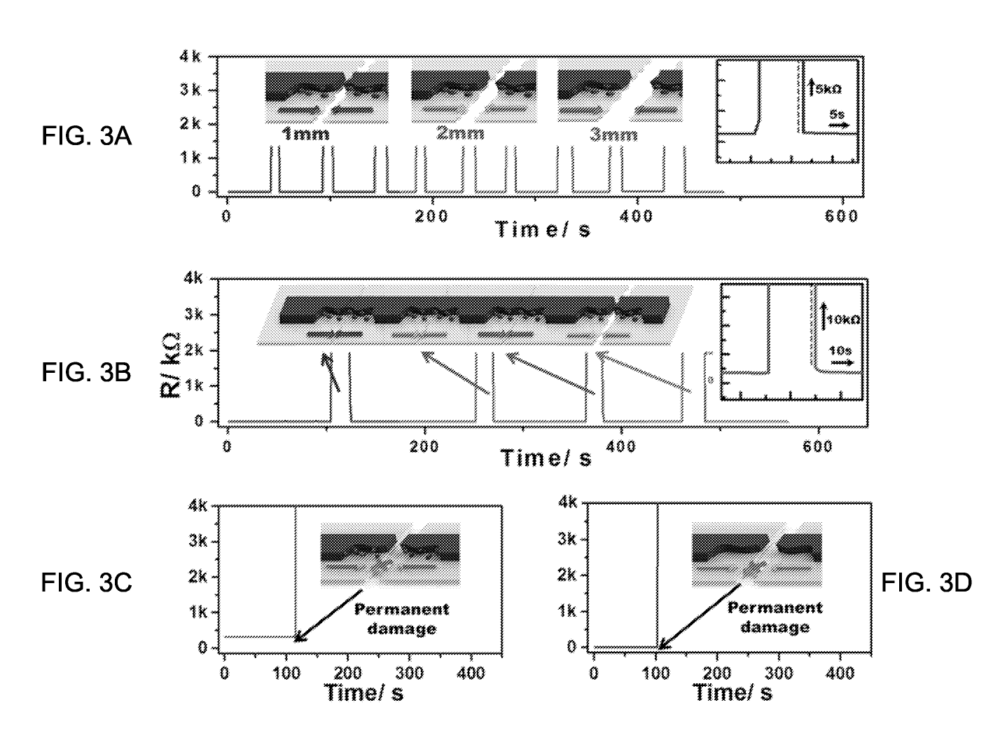

FIG. 4 shows data plots for a cyclic voltammetric (CV) analysis of example printed self-healing traces at various conditions, including varying amounts of NMPs and at different scan rates. Plot (A) of FIG. 4 shows the CV analysis of the example printed self-healing traces with varying amounts of NMPs, e.g., 0%, 15%, 35%, and 55%. Plot (B) of FIG. 4 shows the CV analysis of the example printed self-healing traces with NMPs at different scan rates, e.g., 25 mV/s to 200 mV/s. Plot (C) of FIG. 4 shows a data plot depicting linear dependence of anodic (black plot 431) and cathodic (red plot 432) peak current versus square root of scan rate. Plot (D) of FIG. 4 shows an example Nyquist plot for self-healing printed electrode, in which the inset of plot (D) illustrates a schematic showing the electrical circuit simulating the electrode-electrolyte interface). Plot (E) of FIG. 4 shows CV plots recorded for a self-healing trace before any damage (black plot 451), after first damage with width=1 mm (red plot 452) and after nine repeated damages (blue plot 453) at the same location (e.g., three of each width=1, 2, and 3 mm). Plot (F) of FIG. 4 shows CV plot illustrating real-time recovery of 3 repeated 3 mm-wide damages. Plots (G), (H) and (I) show example individual CV plots showing the point at which the electrode is damaged and the point where the self-healing is initiated for a 1st (plot (G)), a 2nd (plot (H)), and a 3rd (plot (I)) consecutive 3-mm wide damage at the same location (e.g., ‘ci’ to ‘ciii’ represent the time when the electrode was damaged by 3 mm for the three times, while ‘hi’ to ‘hiii’ represent the time when the healing process began after the corresponding damage). In plots (G), (H) and (I), the green, black and red colors represent data before cutting, during damage and after healing, respectively.

Printed electrodes with different NMP loadings (e.g., 0-55 wt %) were prepared and their CV plots were recorded. As evident from panel (A) of FIG. 4, the redox peak potentials for the ferricyanide probe remains nearly unchanged; however, the peak height as well as the background current increase for electrodes containing NMPs. The increase in the peak heights implies that the introduction of NMPs increases the electro-active surface area, while the larger capacitive nature of the electrode could be attributed to increased adsorption of ions onto the electrodes due to the incorporation of NMPs.

CV was also employed to study the reversibility of electrochemical reactions occurring at the self-healing electrodes by recording CV plots at different scan rates. Plot (B) of FIG. 4 reveals that the redox peak positions mildly shift away from each other with increasing scan rate, while plot (C) of FIG. 4 shows the linear dependence of the anodic and cathodic peak currents on the square root of the scan rate. These example findings imply that the electrochemical reaction occurring at the self-healing electrode is diffusion-controlled and has a quasi-reversible nature. These example data sets indicate that the introduction of NMPs within the graphitic ink has a negligible impact on the nature of the electrochemical reaction occurring at the electrode surface.

Thereafter, electrochemical impedance spectroscopy (EIS) technique was used to identify an equivalent circuit model that represents the self-healing electrode-electrolyte interface. Interpretation of the data acquired from this example study, shown in plot (D) of FIG. 4, suggest that the interface can be modeled as Randles circuit comprising of resistors representing solution resistance (Rₛ), charge transfer resistance (Rₚ), Warburg impedance (Z_{w}) for simulating diffusion controlled processes and common phase element (CPE) representing the non-ideal capacitive nature of the interface, e.g., shown in the inset of plot (D).

For example, to study the real-time self-recovery of a printed electrode's electrochemical properties, its CV response was recorded continuously while the electrode was subjected to multiple healing cycles. The damage width was increased from 1 mm to 3 mm (e.g., 1 mm steps). For each damage width, the damage-heal process was repeated three times. Plot (E) of FIG. 4 depicts the voltammograms recorded for a self-healing printed electrode before (black plot 451), after the first healing process for a damage width of 1 mm (red plot 452) and after it was damaged for 9 times (e.g., 3 times each for damage width of 1, 2 and 3 mm) at the same location (blue plot 453). It can be observed that the CV response for the electrode shifts mildly for the first and ninth damage-heal cycles (red plot 452 and blue plot 453, respectively) as compared to its initial un-damaged state (black plot 451). These mild variations reflect slight resistance changes during the repeated extreme degree of damage to which the electrode has been subjected.

Plot (F) of FIG. 4 illustrates the real-time CV recorded for the electrode when it is repeatedly damaged with a crack width of 3 mm for three times. The data proves that the electrode recovers its electrochemical properties rapidly even when exposed to repeated severe levels of damage.

Plots (G), (H) and (I) of FIG. 4 show a single CV cycle illustrating the self-healing process for each of the damage. For example, it is evident that the self-recovery of the electrochemical response takes place rapidly. Similar to the electrical conductivity studies, in the CV studies too, the time required to generate the damage with precise width is much longer than the time required by the system to self-heal.

Self-Healing Batteries, Electrochemical Sensors and Wearable Fabric Circuits

In some embodiments, the magnetic self-healing material articles can be utilized in devices to make self-healing devices. For example, the example NMP-based ink can be used to fabricate self-healing batteries, electrochemical sensors and wearable fabric circuits. Printed batteries are gaining tremendous interest as a viable energy source for a rich variety of applications where mechanical damages are quite common. In an example proof-of-principle of such self-healing device embodiments, a self-healing Zn—Ag₂O battery was fabricated and subjected to multiple damage-heal cycles with current output being recorded continuously.

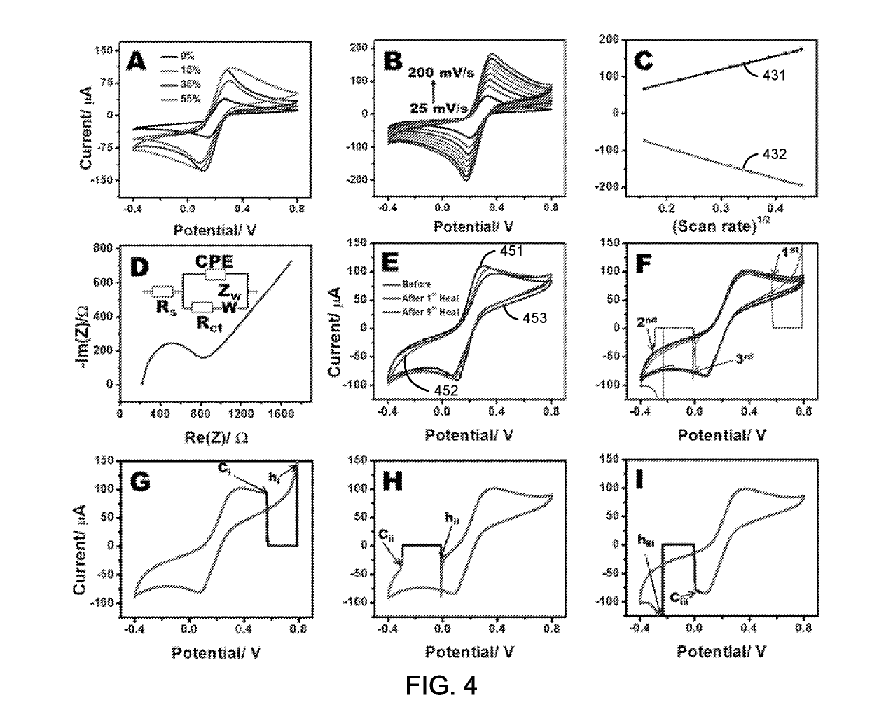

FIGS. 5A-5D show data plots and photographs depicting the self-healing ability of an example self-healing Zn—Ag₂O battery. FIG. 5A shows a data plot depicting the recovery of the current output for an example self-healing Zn—Ag₂O battery after every 3-mm wide damage. FIG. 5B shows a series of photographs showing the example self-healing battery at different steps of the damage-heal cycle. FIG. 5C shows a data plot depicting the inability of an example control Zn—Ag₂O battery (e.g., a non-healing CB-ink based device without any NMPs) to recover current output after the first damage. FIG. 5D shows a series of photographs showing the example control battery at different steps of the damage-heal cycle.

As shown in FIG. 5A, the example self-healing Zn—Ag₂O battery readily recovers its current output capacity even when it is repeatedly damaged by cracks as wide as 3 mm, e.g., shown by the photographs of FIG. 5B. Similarly, the experiment was also conducted for a control system fabricated using CB ink (e.g., no NMPs). The data plot of FIG. 5C and images of FIG. 5D demonstrate the inability of the control battery system to self-recover its performance. For example, a self-healing battery is of interest. However, conventional systems mandate the two severed pieces to be manually held together for a considerable amount of time to complete the self-healing process. In contrast, the example system in accordance with the present technology does not require user intervention and it self-heals autonomously and instantaneously within a fraction of a second.

Similar to printed batteries, electrochemical sensors are being widely utilized for various applications wherein the sensors can be potentially damaged due to mechanical stress. In an example proof of principle of such self-healing device embodiments, self-healing electrochemical sensors for detecting H₂O₂ and Cu were fabricated and tested. These analytes were considered due to their importance in healthcare and environmental applications.

FIGS. 5E and 5F show data plots depicting the self-healing ability of example self-healing electrochemical sensors. Specifically, FIGS. 5E and 5F show amperometric and voltammetric data plots, respectively, depicting the response of self-healing H₂O₂ (FIG. 5E) and Cu sensors (FIG. 5F), for increasing concentrations of H₂O₂ (e.g., 0-20 mM) and Cu (e.g., 0-25 ppm) under repeated 1-mm wide damaging. The data plot of FIG. 5E shows the amperometric data acquired by the self-healing H₂O₂ sensor for increasing peroxide concentrations. The electrode was purposely damaged five times at the same location for each H₂O₂ concentration. The example data of FIG. 5E reveals that the sensor recovers its properties almost immediately after such repeated damages and that such damages have minimal impact on the sensor's real-time response and concentration dependence. The Cu sensor was also similarly ruptured during the voltammetric detection process. From FIG. 5F, one can notice that such extreme damages have negligible impact on the metal sensor's performance since the peak position as well as the linear response of the sensor remains unaffected.

The disclosed technology in this patent document can be used to construct various structures, circuits, devices or machines.

In some embodiments, the magnetic self-healing material articles can be utilized in devices to make self-healing wearable sensor devices. For example, the example NMPs-based ink was employed to realize a fabric-based self-healing electrical circuit for potential wearable applications. For this example implementation, an example self-healing trace was printed on the sleeve of a t-shirt and connected in series with an LED and coin battery via conductive threads. A human subject was requested to wear the t-shirt and thereafter the circuit was damaged by cutting the self-healing trace and the underlying fabric. Upon cutting, the circuit was left open and the LED turned OFF. However, the strong magnetic attraction between the two pieces of the printed trace immediately forced them to move towards each other along with the underlying fabric to regain mechanical and electrical connectivity. The LED gradually turned ON as soon as the electrical connectivity was restored between the two pieces. The entire process of damaging and self-restoring of the wearable circuit. It was also observed that the wearable circuit could rapidly self-heal repeated damages.

FIG. 6 shows an illustrative diagram depicting the autonomous self-healing ability of an example self-healing wearable circuits in accordance with the disclosed technology. The diagram shows three different states of the example self-healing wearable circuit device as an example based on the disclosed self-healing magnetic structures. The three different states include “undamaged” (left drawing), “damaged” (middle drawing) and “healed” (right drawing). Under the normal operational condition (“undamaged”), a LED indicator or other indicator coupled to the device receives electrical power and is turned on to indicate the “normal” or “undamaged” condition of the device. Once damaged, the electrical path in connection with the power supply to the LED indicator is broken and thus the power supply to the LED indicator is turned off to cause the LED to stop emitting light. Based on the self-healing structures disclosed above, the damaged structure can be self-healed or repaired to reestablish the electrical path in the repaired location so that the LED indicator can resume emission of light. (can be used for circuits on conventional substrates like in PCB, plastics).

The example implementations illustrate the ability of example self-healing articles, devices and systems in accordance with the present technology to be used in potential wearable applications. Moreover, these example implementations demonstrate the competence of the present technology to self-heal even when the underlying substrate is much heavier than the printed film. This attractive property can be attributed to the strong magnetic nature of the NMPs, for example. A similar experiment with a control system comprising of a trace fabricated using CB ink (no NMPs) was also conducted. As visibly demonstrated, the control system failed to recover even when the two pieces are manually forced to stick together. Such real-life demonstration of the present self-healing system highlights its potential for realizing self-healing printed devices for diverse practical applications.

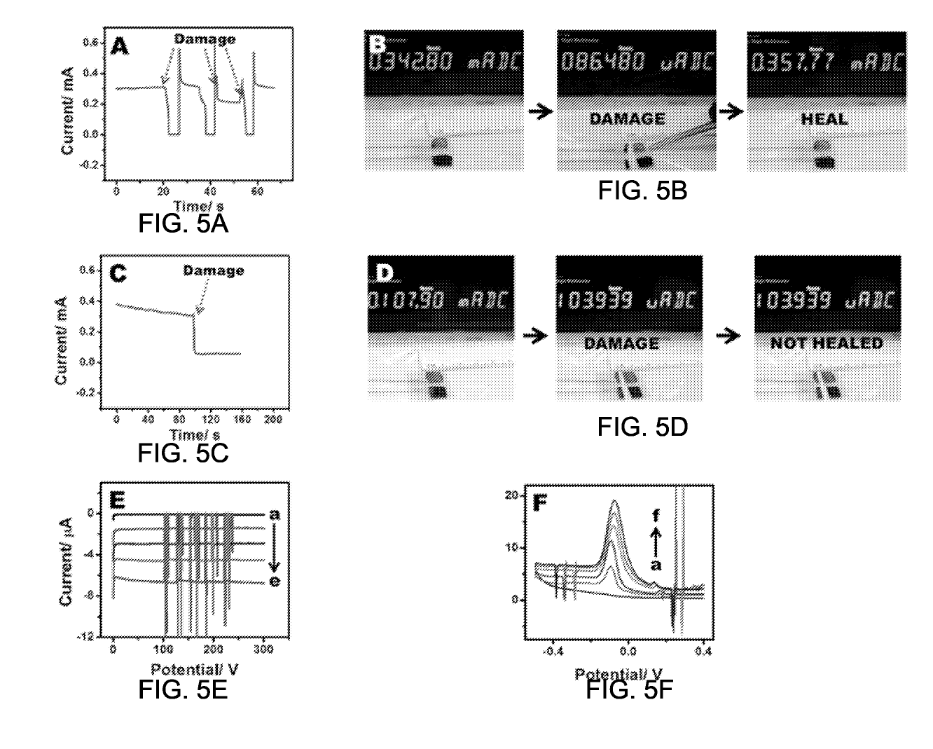

FIG. 7 shows an illustrative diagram depicting another example for using an example self-healing device in accordance with the disclosed technology, such as a battery. The example self-healing battery may be formed to include battery anode and cathode over a substrate as shown in FIG. 7. When subject to damage as shown in the middle drawing, the example battery including the self-healing material can self-repair the damaged portion to regain the normal operating structure, as depicted in the right drawing.

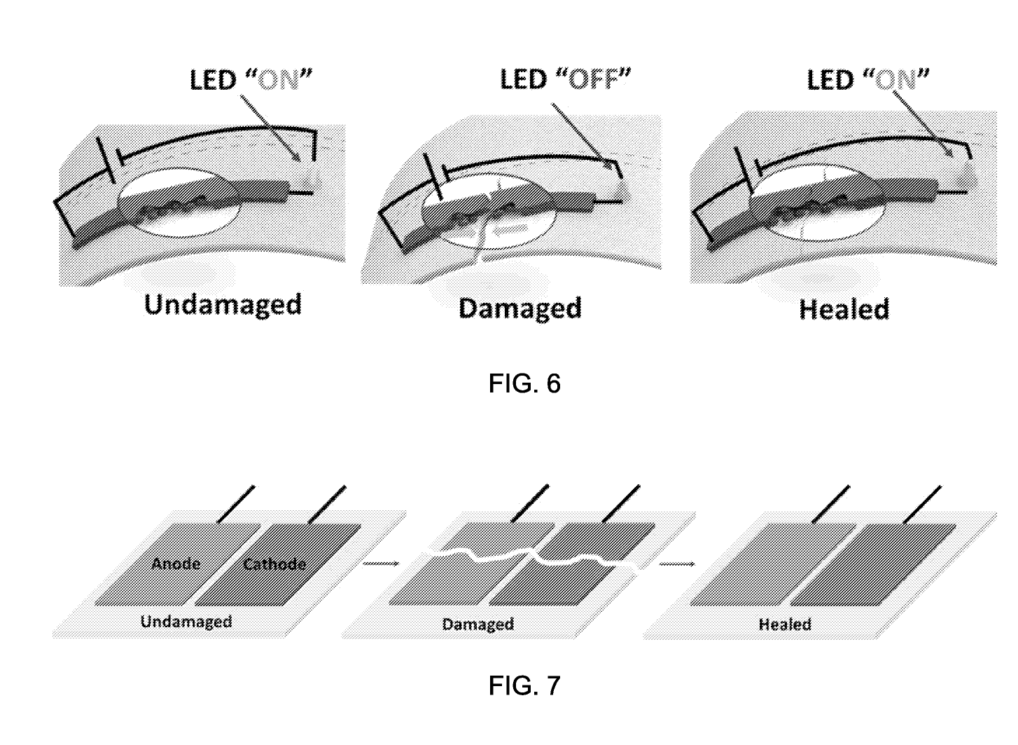

FIG. 8 shows an illustrative diagram depicting another example for using an example self-healing device in accordance with the disclosed technology, such as a sensor. The example sensor device shown in FIG. 8 is an electrochemical sensor including a working electrode (W.E.), a reference electrode (R.E.), and a counter electrode (C.E.) formed over a substrate. Yet, it is understood that the electrochemical sensor is an example, and the self-healing features of the example can be applied to other sensors. As shown in the middle drawing of the diagram, the example sensor can be damaged to cause failure or malfunction. The example sensor including the self-healing material can self-repair the damaged portion of this sensor to regain the normal operating structure, e.g., shown in the right drawing.

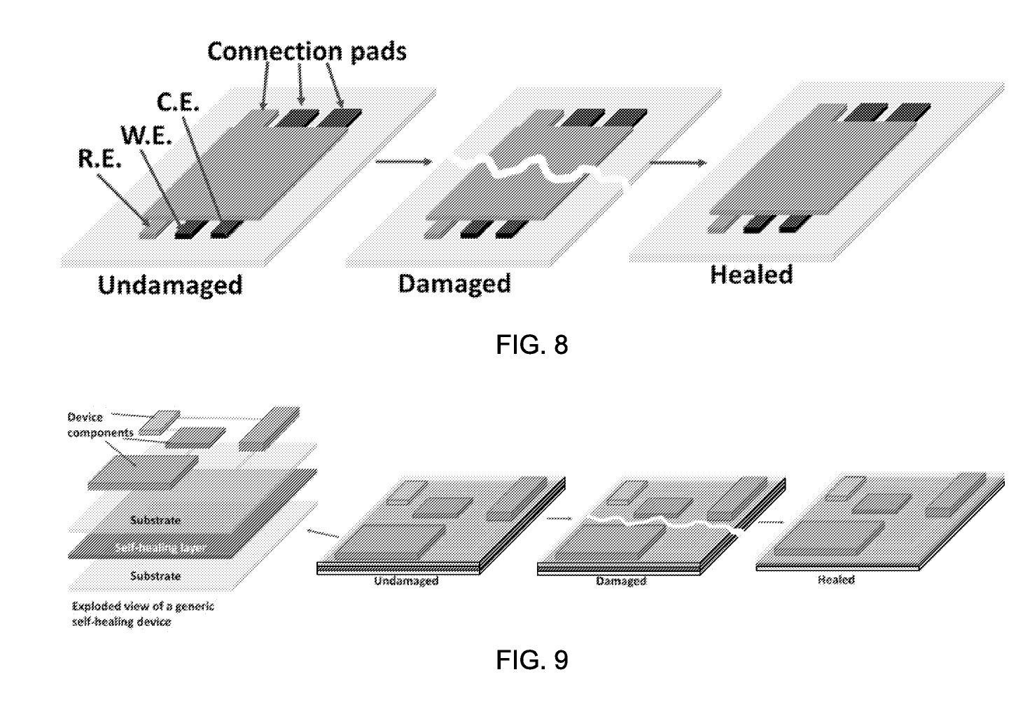

FIG. 9 shows an illustrative diagram of an example self-healing circuit device containing a layer of an example printed magnetically self-healing material to impart a self-healing property to the circuit. The device components are formed on a substrate over the magnetically self-healing layer, which is configured over a lower substrate layer. The device may be damaged to cause failure or malfunction, as shown in the middle drawing. The example sensor including the self-healing material can self-repair the damaged portion of this device to regain the normal operating structure, e.g., shown in the right drawing.

The present work demonstrates the synthesis of magnetically self-healing printable conductive inks for realizing electrical circuits, batteries and electrochemical sensors that rapidly and autonomously restore their properties after experiencing extreme levels of damage. The underlying self-healing principle relies on the strong attraction between example NMPs uniformly dispersed within the ink. Through detailed electrical-conductivity, electrochemical and visual studies described above, for example, it is shown that the printed self-healing devices have the ability to recover their performance almost instantaneously even when repeatedly damaged by macroscopic cracks, as wide as 3 mm, at the same or different locations. For example, a self-healing wearable printed LED circuit was developed by printing a circuit onto a t-shirt. The wearable circuit healed immediately when it was cut along with the underlying fabric. Such impressive self-healing ability can be attributed to the strong magnetic properties of the example NMPs-based self-healing material.

The example NMP-based self-healing system provide several distinct advantages over capsule and intrinsic property-based self-healing systems, such as long-lasting self-healing nature, ability to instantly (e.g., ˜50 ms) heal multiple macroscopic damages without external trigger or user intervention, and insensitivity towards ambient conditions. Such remarkable self-healing of repeated extreme degree of damage has not been reported yet for existing man-made self-healing systems. The impressive healing ability of the NMPs can be further improved by enhancing their magnetic properties. An attractive feature of the permanent magnetic system is its ability to undergo large number of healing cycles under a wide range of ambient conditions. By incorporating various fillers within the NMPs based system one can formulate a rich variety of magnetically-self-healing inks for a wide range of applications. Additionally, the magnetic interaction between the NMPs can be modeled via well-established computer simulations for developing new self-healing inks with tailor made self-healing properties for a variety of applications and broad range of industries. The disclosed technology can be used to produce long-lasting printed electronic devices that can rapidly self-heal macroscopic damages and recover their properties. Such devices are expected to play crucial role in different practical settings where mechanical-damage related device failure is common.

Example Materials and Methods

Chemicals and Reagents

Example chemicals and reagents used in the example implementations included the following. Potassium Ferricyanide, potassium hydroxide (KOH), lithium hydroxide (LiOH), hydrogen peroxide solution (30 wt % in H₂O stabilized), polyacrylic acid (PAA), Polystyrene-block-polyisoprene-block-polystyrene (SIS, styrene 14 wt %), were obtained from Sigma Aldrich (St. Louis, Mo.). Xylene was obtained from Macron Fine Chemicals™, while conductive carbon black (CB) powder was obtained from TIMCAL Graphite & Carbon Super P®. Anhydrous sodium carbonate, Zn and AgO powder were obtained from Fisher Scientific. Copper standard solution was obtained from Fluka Trace CERT™.

Nd₂Fe₁₄B Magnets Grinding Process

The example implementations included a milling process that first involved manually breaking Nd₂Fe₁₄B magnets into small pieces (e.g., ˜1 mm size). Subsequently, the Nd₂Fe₁₄B magnetic powder was further ground into finer microparticles (e.g., ˜5 μm size) in a high-energy ball milling system high energy milling machine (e.g., Fritsh Pulverisette). A 80 mL tempered steel milling bowl and 20 milling balls with diameter of 10 mm were used in the milling process. The milling speed was set at 220 rpm for 3 minutes and repeated for 17 times to obtain NMPs of desired size.

Ink Synthesis

The example implementations included synthesis of the example magnetically self-healing ink, which included first manually grinding conductive CB powder (e.g., 150 mg) with NMPs (e.g., 1173.33 mg). Thereafter the CB-NMPs composite powder was mixed in the SIS polymer suspension (e.g., 810 mg) using a vortex mixer for a couple of minutes. The SIS suspension was previously prepared by dispersing the SIS polymer (e.g., 2000 mg) in xylenes (e.g., 8 mL) for 60 minutes under continuous stirring. Ultimately, the CB and NMPs were thoroughly mixed within the SIS suspension to obtain the self-healing ink by employing a mechanical mixer (SpeedMixer™ FlackTek, Inc.) for 5 times at 2300 rpm for 1 min.

Fabrication Technique for Magnetically Self-Healing Electronic Circuit Components, Such as Printed Electrodes

In some embodiments in accordance with the present technology, a method for producing a self-healing electronic circuit component includes depositing an adhesion layer at a region of a substrate to adhere an electrically conductive material that will form an electronic circuit component; printing a self-healing printable ink over the deposited adhesion layer to form the electronic circuit component; applying a magnetic field one or both of during and after the printing the self-healing printable ink; and forming the electronic circuit component by curing or drying the self-healing printed ink. For example, the self-healing printable ink can include a containment material, a plurality of permanent magnetic particles dispersed in the containment material and oriented with respect to one another such that their magnetic poles are substantially aligned, and a filler material that is electrically conductive, in which the plurality of permanent magnetic particles are configured to autonomously repair a damaged portion of the printable ink based on magnetic attraction of the permanent magnetic particles in the containment material.

In some implementations, the method for producing a self-healing device includes placing a substrate (on which the self-healing device is to be formed) in a permanent magnetic field, e.g., by placing the substrate on a magnet. The method includes placing a stencil having a desired pattern corresponding to the self-healing device over the substrate. The method includes printing the magnetic ink on the stencil-placed substrate. After the design has been registered onto the substrate, the stencil is removed. Due to the presence of the external magnetic field, the magnetic particles within the printed magnetic ink orient themselves along the direction of the magnetic field. Thereafter, the method includes curing the printed device to obtain the printed self-healing device that has a net magnetic field in one direction, e.g., based on the external magnet (e.g., the magnetic field that was applied while printing). For example, when the device is cracked, the cracked pieces act as individual magnets and attract themselves to rejoin.

Example implementations of methods to produce a self-healing electronic component or self-healing device included a fabrication process to produce magnetic self-healing structures that involved screen-printing of the example self-healing conductive ink, e.g., using a MPM-SPM semi-automatic screen printer (e.g., Speedline Technologies, Franklin, Mass.), on a 50 μm thick flexible polyester substrate (e.g., MELINEX® 453). The stencils were designed in AutoCAD (e.g., Autodesk, San Rafael, Calif.) and outsourced for fabrication on stainless steel through-hole 12″×12″ framed stencils with a thickness of 500 μm (e.g., Metal Etch Services, San Marcos, Calif.). The example fabrication process included first thoroughly cleaning the polyester substrate with acetone for removing contaminants. Thereafter, a polyurethane layer of thickness ˜75 μm (e.g., RheoFlex® 20, Smooth On, Macungie, Pa.) was screen printed on top of the substrate and cured at 65° C. for 20 min in a convection oven. The polyurethane layer was included to enhance the adhesion of the self-healing ink to the polyester substrate. The next step involved the printing of the magnetically self-healing ink. Before printing the self-healing ink, a commercial bar magnet with poles directed parallel to the stencil was placed underneath the substrate. After printing the self-healing ink, the substrate was left unmoved for 15 min to allow the NMPs to orient along the direction of the external magnetic field produced by the magnet placed under the substrate. Finally, the printed electrodes were lifted from the magnet and cured at 60° C. for 10 min in a convection oven. A transparent insulator was ultimately printed onto the self-healing electrodes to define the active electrode area and contact pads.

Fabrication Technique for Magnetically Self-Healing Printed Zn—Ag₂O Batteries

The example implementations included a fabrication process to produce magnetic self-healing Zn—Ag₂O batteries that included initially formulating Ag₂O and Zn inks, e.g., by manually mixing the respective powders (e.g., 263 mg) in SIS binder (e.g., 500 mg). The fabrication of magnetically self-healing printed Zn—Ag₂O batteries first included printing two current collectors using the magnetically self-healing ink. Thereafter, Zn and Ag₂O inks were separately printed over each of the current collector electrodes to transform them into the cathode and anode of the printed self-healing battery. The Ag₂O and Zn electrodes were later covered by a gel electrolyte containing 10% poly acrylic acid dispersed in a solution of 6M KOH containing 1M LiOH.

Electrochemical, SEM-EDX and XRD Analysis

Example implementations using self-healing materials and control materials included CV studies that were performed at room temperature using a CH Instruments electrochemical analyzer (model 1232A, Austin, Tex.). For example, the printed electrode was employed as a working electrode while commercial Ag/AgCl and platinum wire electrodes were used as reference and counter electrodes, respectively. Ferricyanide (e.g., 10 mM in 0.1M phosphate buffer, pH 7.0) was utilized as the electrolyte. A scan rate of 0.1V/s was employed for all experiments unless mentioned. EIS data was recorded, similar to CV studies, using a Gamry Instruments potentiostat in the 50 mHz-0.3 MHz frequency range and at a constant DC voltage of 0.2 V. SEM experiments were performed by a FEI/Phillips XL30 ESEM instrument. Energy-dispersive X-ray mapping analysis was performed using an Oxford EDX detector attached to SEM instrument and operated by INCA software. The images were captured at 200× magnification. XRD data was recorded using a Rigaku Rotaflex diffractometer using Cu Kα radiation (λ=0.15418 nm) with an acceleration voltage of 40 keV and tube current of 100 mA. The samples were scanned at a scan rate of 0.5°/s in the range of 20=20-80.

Electrochemical Detection of H₂O₂ and Cu at Self-Healing Electrodes

Example implementations using self-healing materials included amperometric detection of H₂O₂, which was performed at −0.15 V in 0.1M phosphate buffer (pH 7). The magnetic self-healing ability of the electrochemical devices was analyzed while recording the amperometric responses for 0, 5, 10, 15 and 20 mM H₂O₂. The self-healing electrode was damaged five times by a crack width of 1 mm for each peroxide addition. The self-healing electrode was employed for the detection of Cu (0, 5, 10, 15, 20 and 25 ppm) by anodic stripping voltammetry (SWV). The deposition of Cu was performed by applying constant potential of −0.7V for 60 s. Subsequently SWV plots were recorded by potential scan from −0.5 V to 0.4 V (amplitude=25 mV; Frequency=2 Hz; increment E=4 mV). The electrode was damaged twice during the stripping process for each addition. The electrode was electrochemically cleaned by applying a constant potential of 0.3V for 120 s before each deposition process.

Disclosed are compositions, fabrication methods and articles of manufacture that pertain to printable inks comprising permanent magnet microparticles for realizing rapidly self-healing printed devices. The disclosed technology can be used in broad ranges of applications, including, e.g., consumer and security/environmental electronics where device failure via mechanical damage is a major concern.

In an exemplary embodiment, Nd₂Fe₁₄B microparticles (NMPs) are incorporated in custom graphitic inks to impart efficient self-healing ability to the printed films. When the printed film is damaged, the strong magnetic attraction of the dispersed NMPs within the film attract one another and lead to rapid (e.g., ˜50 ms) re-attachment of the broken film. Experimental data reveal that magnetically self-healing printed devices immediately recover their electrical connectivity, electrochemical and battery performance even when the damage crack is as wide as 3 mm. Other permanent magnetic particles can be used to practice this printed self-healing approach. For example, similar ink synthesis routes can be used to include other permanent magnetic particles (samarium-cobalt, ceramic, alnico) and fillers (nanomaterials, ceramics, metals etc.) to cater to a wide range of applications.

The disclosed technology can be used to mitigate degradation and loss of function due to mechanical deformation in consumer electronics, healthcare, defense, construction and space research. The disclosed technology can be used to construct printed devices for diverse applications in wearables, healthcare, and energy which are expected to experience mechanical damage. The disclosed self-healing technologies for printed devices can be used to reduce maintenance costs and extend the lifespan of such devices.

### Examples

The following examples are illustrative of several embodiments in accordance with the present technology. Other exemplary embodiments of the present technology may be presented prior to the following listed examples, or after the following listed examples.

In some embodiments in accordance with the present technology (example A1), a device exhibiting a self-healing property to repair a damage includes a device structure including a plurality of magnetic microparticles dispersed within the device structure and oriented with respect to one another such that their magnetic poles are substantially aligned, in which the plurality of magnetic microparticles are configured to impart a self-healing ability to the device structure such that, when damage occurs to a portion of the device structure, the device structure is able to self-repair based on magnetic attraction of the dispersed magnetic microparticles to cause re-attachment of the portion.

Example A2 includes the device as in example A1, in which the device structure includes a battery.

Example A3 includes the device as in example A1, in which the device structure includes a sensor.

Example A4 includes the device as in example A1, in which the device structure includes an electrochemical sensor formed on a flexible substrate.

Example A5 includes the device as in example A1, in which the device structure includes a circuit.

Example A6 includes the device as in example A1, in which the device structure includes a micromachine.

Example A7 includes the device as in example A1, in which the device structure is part of a mobile device.

Example A8 includes the device as in example A1, in which the device structure is part of a wearable device.

Example A9 includes the device as in example A1, in which the device structure is part of a medical device.

Example A10 includes the device as in example A1, in which the device structure includes a graphitic ink layer in which the magnetic microparticles are dispersed.

Example A11 includes the device as in example A1, in which the magnetic microparticles include Nd₂Fe₁₄B microparticles.

Example A12 includes the device as in example A11, in which the magnetic Nd₂Fe₁₄B microparticles are dispersed in an electrically conductive structure.

Example A13 includes the device as in example A1, in which the magnetic microparticles are dispersed in an electrically conductive structure which forms a part of an electrical conducting path for the device.

In some embodiments in accordance with the present technology (example A14), a method for producing a self-healing electronic circuit component includes depositing an adhesion layer at a region of a substrate to adhere an electrically conductive material that will form an electronic circuit component; printing a self-healing printable ink over the deposited adhesion layer to form the electronic circuit component, in which the self-healing ink includes a containment material, a plurality of permanent magnetic particles dispersed in the containment material and oriented with respect to one another such that their magnetic poles are substantially aligned, and a filler material that is electrically conductive, in which the plurality of permanent magnetic particles are configured to autonomously repair a damaged portion of the printable ink based on magnetic attraction of the permanent magnetic particles in the containment material; applying a magnetic field one or both of during and after the printing the self-healing printable ink; and forming the electronic circuit component by curing or drying the self-healing printed ink.

Example A15 includes the method as in example A14, in which the applying the magnetic field includes placing a magnet proximate the substrate such that poles of the magnet are directed parallel to a desired current path of the electronic circuit component, in which the placing the magnet occurs prior and during the printing the self-healing printable ink.

Example A16 includes the method as in any of examples A14-A15, in which the printing includes screen-printing of the self-healing conductive ink using a stencil placed over the region of substrate.

Example A17 includes the method as in any of examples A14-A16, further including first, cleaning the substrate to remove potential contaminants.

Example A18 includes the method as in any of examples A14-A17, in which the substrate includes an electrically insulating material.

Example A19 includes the method as in example A18, in which the substrate includes a flexible material including a textile.

Example A20 includes the method as in any of examples A14-A19, in which the adhesive layer includes a polyurethane layer.

Example A21 includes the method as in any of examples A14-A20, further including, prior to the printing the self-healing printable ink, curing the deposited adhesion layer.

Example A22 includes the method as in any of examples A14-A21, in which the magnetic field is applied for at least 15 minutes.

Example A23 includes the method as in any of examples A14-A22, further including printing a transparent insulator material over at least a portion of the electronic circuit component formed of the self-healing printed ink to define one or more of an electrode, or a contact pad.

Example A24 includes the method as in any of examples A14-A23, in which the self-healing ink further includes elastomeric polymers contained in the containment material, in which the elastomeric polymers are configured to assist in the autonomous repair of the damaged portion of the printable ink, in which the elastomeric polymers undergo chemical interaction to form permanent bonds to seal reconnected portions that are reconnected based on the magnetic attraction of the permanent magnetic particles.

In some embodiments in accordance with the present technology (example A25), a self-healing article includes a containment material; and a plurality of permanent magnetic particles dispersed in the containment material and oriented with respect to one another such that their magnetic poles are substantially aligned, in which the plurality of permanent magnetic particles are configured to autonomously repair a damage to the article based on magnetic attraction of the permanent magnetic particles in the containment material.

Example A26 includes the article as in example A25, in which the permanent magnetic particles include Nd₂Fe₁₄B microparticles.

Example A27 includes the article as in any of examples A25-A26, in which the permanent magnetic particles include a ferromagnetic or ferrimagnetic material having a coercivity of at least 70 Oe.

Example A28 includes the article as in any of examples A25-A27, in which the permanent magnetic particles are microparticles structured to have a size in a range of 1 μm to 10 μm.

Example A29 includes the article as in any of examples A25-A28, in which the permanent magnetic particles are nanoparticles structured to have a size in a range of 100 nm to 1,000 nm.

Example A30 includes the article as in any of examples A25-A29, in which the permanent magnetic particles include alnico alloy (AlNiCo), samarium cobalt (SmCo₅), BaO-6Fe₂O₃, cunife, or tungsten steel.

Example A31 includes the article as in any of examples A25-A30, in which the containment material includes a liquid or gel medium.

Example A32 includes the article as in any of examples A25-A31, in which the containment material includes one or more of a solvent, a pigment, a dye, a resin, a lubricant, a solubilizer, a surfactant, a particulate, or a fluorescent substance.

Example A33 includes the article as in any of examples A25-A32, in which the containment material includes one or more of an enzyme, an antibody, an electrochemical redox species, or a nanoparticle or a microparticle comprising at least one of a metal, a metal oxide, a metal chalcogenide, a ceramic, or a quantum dot.

Example A34 includes the article as in any of examples A25-A33, in which the permanent magnetic particles are dispersed in the containment material to allow a shift or change in orientation of the permanent magnetic particles within the containment material to orient themselves according to one or both of their own magnetic properties or in response to an external magnetic field applied to the article.

Example A35 includes the article as in any of examples A25-A34, further including elastomeric polymers contained in the containment material, in which, in combination with the permanent magnetic particles, the elastomeric polymers are operable to assist in autonomously repairing damage to the article when damaged, in which the permanent magnetic particles cause reconnection of damaged portions of the article based on the magnetic attraction of the permanent magnetic particles in the containment material, and after the damaged portions are connected, the elastomeric polymers undergo chemical interaction to form permanent bonds to seal reconnected portions.

Example A36 includes the article as in any of examples A25-A35, in which the article is a printable ink.

Example A37 includes the article as in example A36, further including a filler material comprising carbon black.

Example A38 includes the article as in example A37, in which the printable ink includes an ink binder comprising polystyrene-block-polyisoprene-block-polystyrene (SIS).

Example A39 includes the article as in any of examples A25-A38, in which the article is an electrically conductive component of one or more of a circuit, a battery, a sensor, a micromachine, or a medical device.

In some embodiments in accordance with the present technology (example A40), a printable ink includes an ink binder material; a plurality of permanent magnetic particles dispersed in the ink binder material and oriented with respect to one another such that their magnetic poles are substantially aligned; and a filler material contained in the ink binder, in which the filler material is electrically conductive, in which the printable ink is structured to autonomously self-repair a damaged portion based on orientation of the permanent magnetic particles in the ink binder to produce an anisotropic magnetic field within the printable ink.

Example A41 includes the printable ink as in example A40, in which filler material includes carbon black.

Example A42 includes the printable ink as in any of examples A40-A41, in which the ink binder includes polystyrene-block-polyisoprene-block-polystyrene (SIS).

Example A43 includes the printable ink as in any of examples A40-A42, in which the permanent magnetic particles include Nd₂Fe₁₄B microparticles.

Example A44 includes the printable ink as in example A43, in which the Nd₂Fe₁₄B microparticles are microparticles structured to have a size in a range of 1 μm to 100 μm.

Example A45 includes the printable ink as in example A43, in which the Nd₂Fe₁₄B microparticles are nanoparticles structured to have a size in a range of 100 nm to 1,000 nm.

Example A46 includes the printable ink as in any of examples A40-A45, in which the printable ink is an electrically conductive component of one or more of a circuit, a battery, a sensor, a micromachine, or a medical device.

Example A47 includes the printable ink as in any of examples A40-A46, further including elastomeric polymers contained in the ink binder material, in which the elastomeric polymers are configured to assist in the self-repair of the damaged portion of the printable ink, in which the elastomeric polymers undergo chemical interaction to form permanent bonds to seal reconnected portions of the printable ink that are reconnected based on the magnetic attraction of the permanent magnetic particles.

Example A48 includes the printable ink as in any of examples A40-A47, in which the ink binder material includes one or more of an enzyme, an antibody, an electrochemical redox species, or a nanoparticle or a microparticle comprising at least one of a metal, a metal oxide, a metal chalcogenide, a ceramic, or a quantum dot.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

1. A device exhibiting a self-healing property to repair a damage, comprising:
a device structure including a plurality of magnetic microparticles dispersed within the device structure to substantially alignmagnetic poles of the magnetic microparticles with respect to one another, wherein the plurality of magnetic microparticles are configured to impart a self-healing ability to the device structure such that, when damage occurs to a portion of the device structure, the device structure is able to self-repair based on magnetic attraction of the dispersed magnetic microparticles to cause re-attachment of the portion,
wherein the device structure includes at least one of a battery, a sensor, or an electrochemical sensor formed on a flexible substrate.

2.-9. (canceled)

10. The device as in claim 1, wherein the device structure includes a graphitic ink layer in which the magnetic microparticles are dispersed.

11.-12. (canceled)

13. The device as in claim 1, wherein the magnetic microparticles are dispersed in an electrically conductive structure which forms a part of an electrical conducting path for the device.

14. A method for producing a self-healing electronic circuit component, comprising:
depositing an adhesion layer at a region of a substrate to adhere an electrically conductive material that will form an electronic circuit component;
printing a self-healing printable ink over the deposited adhesion layer to form the electronic circuit component, wherein the self-healing ink includes:
a containment material,
a plurality of permanent magnetic particles dispersed in the containment material and oriented such that magnetic poles of the permanent magnetic particles are substantially aligned, and
a filler material that is electrically conductive, wherein the plurality of permanent magnetic particles are configured to autonomously repair a damaged portion of the printable ink based on magnetic attraction of the permanent magnetic particles in the containment material;
applying a magnetic field one or both of during and after the printing the self-healing printable ink; and
forming the electronic circuit component by curing or drying the self-healing printed ink.

15. The method as in claim 14, wherein the applying the magnetic field includes placing a magnet proximate the substrate such that poles of the magnet are directed parallel to a desired current path of the electronic circuit component, wherein the placing the magnet occurs prior and during the printing the self-healing printable ink.

16. The method as in claim 14, wherein the printing includes screen-printing of the self-healing conductive ink using a stencil placed over the region of substrate.

17. The method as in claim 14, further comprising:
first, cleaning the substrate to remove potential contaminants.

18.-20. (canceled)

21. The method as in claim 14, further comprising:
prior to the printing the self-healing printable ink, curing the deposited adhesion layer.

22. (canceled)

23. The method as in claim 14, further comprising:
printing a transparent insulator material over at least a portion of the electronic circuit component formed of the self-healing printed ink to define one or more of an electrode, or a contact pad.

24. The method as in claim 14, wherein the self-healing ink further includes elastomeric polymers contained in the containment material, wherein the elastomeric polymers are configured to assist in the autonomous repair of the damaged portion of the printable ink, in which the elastomeric polymers undergo chemical interaction to form permanent bonds to seal reconnected portions that are reconnected based on the magnetic attraction of the permanent magnetic particles.

25. A self-healing article, comprising:
a containment material; and
a plurality of permanent magnetic particles dispersed in the containment material and oriented with respect to one another such that magnetic poles of the permanent magnetic particles are substantially aligned, wherein the plurality of permanent magnetic particles are configured to autonomously repair a damage to the article based on magnetic attraction of the permanent magnetic particles in the containment material.

26. The article as in claim 25, wherein the permanent magnetic particles include Nd₂Fe₁₄B microparticles.

27. The article as in claim 25, wherein the permanent magnetic particles include a ferromagnetic or ferrimagnetic material having a coercivity of at least 70 Oe.

28. The article as in claim 25, wherein the permanent magnetic particles are microparticles structured to have a size in a range of 1 μm to 10 μm.

29. The article as in claim 25, wherein the permanent magnetic particles are nanoparticles structured to have a size in a range of 100 nm to 1,000 nm.

30. The article as in claim 25, wherein the permanent magnetic particles include alnico alloy (AlNiCo), samarium cobalt (SmCo₅), BaO-6Fe₂O₃, cunife, or tungsten steel.

31. The article as in claim 25, wherein the containment material includes a liquid or gel medium.

32. The article as in claim 25, wherein the containment material includes one or more of a solvent, a pigment, a dye, a resin, a lubricant, a solubilizer, a surfactant, a particulate, or a fluorescent substance.

33. The article as in claim 25, wherein the containment material includes one or more of an enzyme, an antibody, an electrochemical redox species, or a nanoparticle or a microparticle comprising at least one of a metal, a metal oxide, a metal chalcogenide, a ceramic, or a quantum dot.

34. The article as in claim 25, wherein the permanent magnetic particles are dispersed in the containment material to allow a shift or change in orientation of the permanent magnetic particles within the containment material to orient themselves according to one or both of their own magnetic properties or in response to an external magnetic field applied to the article.

35. The article as in claim 25, further comprising:
elastomeric polymers contained in the containment material,
wherein, in combination with the permanent magnetic particles, the elastomeric polymers are operable to assist in autonomously repairing damage to the article when damaged, in which the permanent magnetic particles cause reconnection of damaged portions of the article based on the magnetic attraction of the permanent magnetic particles in the containment material, and after the damaged portions are connected, the elastomeric polymers undergo chemical interaction to form permanent bonds to seal reconnected portions.

36. The article as in claim 25, wherein the article is a printable ink.

37. The article as in claim 36, further comprising a filler material comprising carbon black.

38. The article as in claim 37, wherein the printable ink includes an ink binder comprising polystyrene-block-polyisoprene-block-polystyrene (SIS).

39. The article as in claim 25, wherein the article is an electrically conductive component of one or more of a circuit, a battery, a sensor, a micromachine, or a medical device.

40.-48. (canceled)
